(19) United States
(12) Patent Application Publication
(10) Pub. No.: US 2025/0351705 A1
(43) Pub. Date: Nov. 13, 2025

(54) DISPLAY DEVICE AND MANUFACTURING METHOD OF DISPLAY DEVICE

(71) Applicant: Japan Display Inc., Tokyo (JP)

(72) Inventors: Hiraaki KOKAME, Tokyo (JP); Akinori KAMIYA, Tokyo (JP); Kaoru ABE, Tokyo (JP)

(73) Assignee: Japan Display Inc., Tokyo (JP)

(21) Appl. No.: 19/098,056

(22) Filed: Apr. 2, 2025

(30) Foreign Application Priority Data
May 8, 2024 (JP) 2024-075934

(51) Int. Cl. H10K 59/80; H10K 59/12; H10K 59/122

(52) U.S. Cl. CPC H10K 59/871; H10K 59/1201; H10K 59/122

(57) ABSTRACT

According to one embodiment, a display device includes a lower electrode, an organic layer which includes a light emitting layer, an upper electrode, a cap layer, a partition which has a lower portion and an upper portion, and surrounds the organic layer, the upper electrode and the cap layer, a first sealing layer which is formed of an inorganic insulating material, is provided on the cap layer surrounded by the partition, is in contact with a side surface of the partition, extends to an upper side of the partition, and is spaced apart from the upper portion of the partition, and a second sealing layer which is formed of an inorganic insulating material and directly covers the first sealing layer.

### CROSS-REFERENCE TO RELATED APPLICATION

This application is based upon and claims the benefit of priority from Japanese Patent Application No. 2024-075934, filed May 8, 2024, the entire contents of which are incorporated herein by reference.

### FIELD

Embodiments described herein relate generally to a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

The reduction in the manufacturing cost of display devices is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view showing a configuration example of the display device DSP along the A-B line of FIG. 2.

FIG. 4 is a schematic cross-sectional view showing a configuration example of the display device DSP along the I-I′ line of FIG. 1.

FIG. 5 is a cross-sectional view in which a void GP is enlarged.

FIG. 6 is a diagram showing a configuration example of a display element DE.

FIG. 7 is a diagram for explaining the outline of a manufacturing device.

FIG. 8A is a diagram showing a configuration example of the evaporation device 100 shown in FIG. 7.

FIG. 8B is a diagram showing another configuration example of the evaporation device 100 shown in FIG. 7.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram for explaining the manufacturing method of the display device DSP.

FIG. 19 is a diagram for explaining the manufacturing method of the display device DSP.

FIG. 20 is a diagram for explaining the manufacturing method of the display device DSP.

FIG. 21 is a diagram for explaining the manufacturing method of the display device DSP.

FIG. 22 is a diagram for explaining the manufacturing method of the display device DSP.

FIG. 23 is a schematic cross-sectional view showing another configuration example of the display device DSP along the A-B line of FIG. 2.

FIG. 24 is a schematic cross-sectional view showing another configuration example of the display device DSP along the I-I′ line of FIG. 1.

FIG. 25 is a diagram for explaining the manufacturing method of the display device DSP.

### DETAILED DESCRIPTION

Embodiments described herein aim to provide a display device and a manufacturing method of a display device such that the manufacturing cost can be reduced.

In general, according to one embodiment, a display device comprises a substrate, a lower electrode provided in a display area which displays an image above the substrate, an insulating layer which is formed of an inorganic insulating material and covers a peripheral portion of the lower electrode, an organic layer which is provided on the lower electrode and includes a light emitting layer, an upper electrode provided on the organic layer, a cap layer provided on the upper electrode, a partition which has a lower portion provided on the insulating layer, being in contact with the upper electrode and formed of a conductive material, and an upper portion provided on the lower portion, and surrounds the organic layer, the upper electrode and the cap layer, a first sealing layer which is formed of an inorganic insulating material, is provided on the cap layer surrounded by the partition, is in contact with a side surface of the partition, extends to an upper side of the partition, and is spaced apart from the upper portion of the partition, and a second sealing layer which is formed of an inorganic insulating material and directly covers the first sealing layer.

According to another embodiment, a display device comprises a substrate, a lower electrode provided in a display area which displays an image above the substrate, an insulating layer which is formed of an inorganic insulating material and covers a peripheral portion of the lower electrode, an organic layer which is provided on the lower electrode and includes a light emitting layer, an upper electrode provided on the organic layer, a cap layer provided on the upper electrode, a partition which has a lower portion provided on the insulating layer, being in contact with the upper electrode and formed of a conductive material, and an upper portion provided on the lower portion, and surrounds the organic layer, the upper electrode and the cap layer, a first sealing layer which is formed of an inorganic insulating material, is provided on the cap layer surrounded by the partition, is in contact with a side surface of the partition, extends to an upper side of the partition, and is spaced apart from the upper portion of the partition, and a resin layer which directly covers the first sealing layer. The resin layer is not covered with an inorganic insulating layer.

According to yet another embodiment, a manufacturing method of a display device comprises preparing a processing substrate by forming a lower electrode above a substrate, forming an insulating layer which covers a peripheral portion of the lower electrode, and forming a partition which has a lower portion located on the insulating layer and an upper portion located on the lower portion, forming an organic layer including a light emitting layer on the lower electrode, forming an upper electrode on the organic layer, forming a cap layer on the upper electrode, forming a first sealing layer which is formed of an inorganic insulating material and covers the cap layer and the partition, forming a second sealing layer which is formed of an inorganic insulating material and directly covers the first sealing layer, and forming a resin layer which covers the second sealing layer.

The embodiments can provide a display device and a manufacturing method of a display device such that the manufacturing cost can be reduced.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”, and the negative direction of the Z-axis is referred to as “below” or “under”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

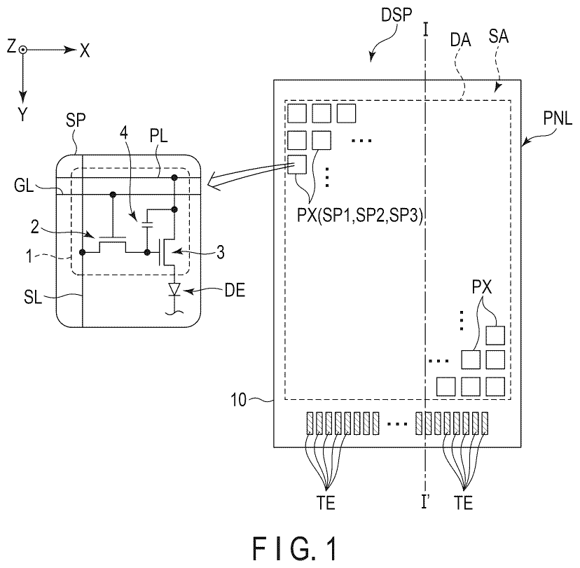

FIG. 1 is a diagram showing a configuration example of a display device DSP.

The display device DSP comprises a display panel PNL having a display area DA which displays images and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA comprises a plurality of terminals TE which are arranged along one direction. In the example shown in the figure, the terminals TE are arranged in the first direction X. Each of the terminals TE extends in the second direction Y. However, the configuration is not limited to this example. For example, these terminals TE are electrically connected to signal sources such as a flexible printed circuit and an IC chip. Further, these terminals TE are electrically connected to the various wiring lines of the display area DA (the scanning lines, the signal lines, the power lines, the wiring lines for a touch sensor and the like).

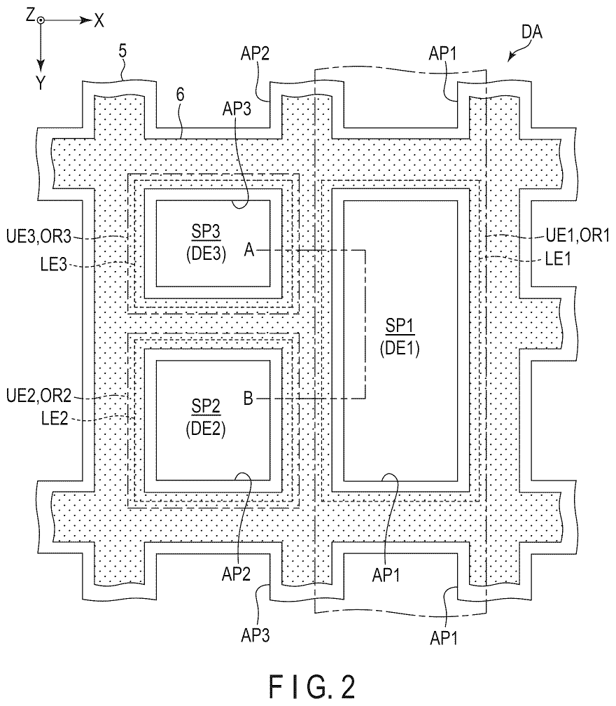

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An insulating layer 5 and a partition 6 are provided in the display area DA. The insulating layer 5 has apertures AP1, AP2 and AP3 in subpixels SP1, SP2 and SP3, respectively. The insulating layer 5 having these apertures AP1, AP2 and AP3 may be called a rib.

The partition 6 overlaps the insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the insulating layer 5. The partition 6 is conductive and is electrically connected to, of the terminals TE shown in FIG. 1, each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The peripheral portion of the lower electrode LE1 is covered with the insulating layer 5. The display element DE1 comprising the lower electrode LE1, the organic layer OR1 and the upper electrode UE1 is surrounded by the partition 6 in plan view. The peripheral portion of each of the organic layer OR1 and the upper electrode UE1 overlaps the insulating layer 5 in plan view. The organic layer OR1 includes a light emitting layer which emits light in, for example, a blue wavelength range.

The display element DE2 of subpixel SP2 comprises a lower electrode LE2, an upper electrode UE2 and an organic layer OR2 overlapping the aperture AP2. The peripheral portion of the lower electrode LE2 is covered with the insulating layer 5. The display element DE2 comprising the lower electrode LE2, the organic layer OR2 and the upper electrode UE2 is surrounded by the partition 6 in plan view. The peripheral portion of each of the organic layer OR2 and the upper electrode UE2 overlaps the insulating layer 5 in plan view. The organic layer OR2 includes a light emitting layer which emits light in, for example, a green wavelength range.

The display element DE3 of subpixel SP3 comprises a lower electrode LE3, an upper electrode UE3 and an organic layer OR3 overlapping the aperture AP3. The peripheral portion of the lower electrode LE3 is covered with the insulating layer 5. The display element DE3 comprising the lower electrode LE3, the organic layer OR3 and the upper electrode UE3 is surrounded by the partition 6 in plan view. The peripheral portion of each of the organic layer OR3 and the upper electrode UE3 overlaps the insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1. The lower electrode LE2 is electrically connected to the pixel circuit 1 of subpixel SP2. The lower electrode LE3 is electrically connected to the pixel circuit 1 of subpixel SP3.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

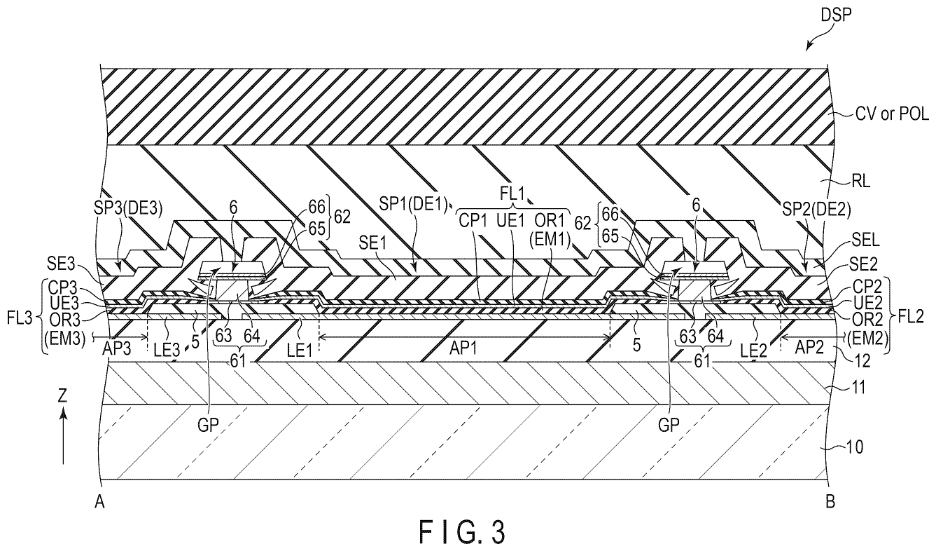

FIG. 3 is a schematic cross-sectional view showing a configuration example of the display device DSP along the A-B line of FIG. 2.

A circuit layer 11 is provided on the substrate 10. The circuit layer 11 includes various circuits such as the pixel circuits 1 shown in FIG. 1 and various lines such as the scanning lines GL, the signal lines SL and the power lines PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The insulating layer 5 is provided on the insulating layer 12 and the lower electrodes LE1, LE2 and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 has a conductive lower portion 61 provided on the insulating layer 5, and an upper portion 62 provided on the lower portion 61.

In the example shown in the figure, the lower portion 61 has a bottom layer 63 provided on the insulating layer 5, and a stem layer 64 provided between the bottom layer 63 and the upper portion 62. The bottom layer 63 is thinner than the stem layer 64. The bottom layer 63 has a width greater than that of the stem layer 64. The both end portions of the bottom layer 63 protrude from the side surfaces of the stem layer 64.

The upper portion 62 has a thin film 65 provided on the stem layer 64 and a thin film 66 provided on the thin film 65. The upper portion 62 has a width greater than that of the stem layer 64. The both end portions of the upper portion 62 protrude from the side surfaces of the stem layer 64. In this specification, the side surfaces of the stem layer 64 are assumed to be, of the stem layer 64, the surfaces which extend between the bottom layer 63 and the upper portion 62.

In the example shown in the figure, the upper portion 62 has a width greater than that of the bottom layer 63. It should be noted that the bottom layer 63 may have a width greater than that of the upper portion 62.

The organic layer OR1 is in contact with the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and is in contact with the lower portion 61.

It should be noted that the contact between each of the upper electrodes UE1, UE2 and UE3 and the lower portion 61 includes a case where each of the upper electrodes UE1, UE2 and UE3 is directly in contact with the upper surface of the bottom layer 63 and a case where each of the upper electrodes UE1, UE2 and UE3 is directly in contact with the upper surface of the bottom layer 63 and is further directly in contact with a side surface of the stem layer 64. In this specification, the upper surface of the bottom layer 63 is assumed to include, of the bottom layer 63, the surface which is directly in contact with the stem layer 64, and the surface which protrudes from the stem layer 64 and faces the upper portion 62.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1. Thus, the sealing layer SE1 is in contact with the stem layer 64 and upper portion 62 of the partition 6 which surrounds the display element DE1.

The sealing layer SE2 is provided on the cap layer CP2, is in contact with the partition 6 and continuously covers each member of subpixel SP2. Thus, the sealing layer SE2 is in contact with the stem layer 64 and upper portion 62 of the partition 6 which surrounds the display element DE2.

The sealing layer SE3 is provided on the cap layer CP3, is in contact with the partition 6 and continuously covers each member of subpixel SP3. Thus, the sealing layer SE3 is in contact with the stem layer 64 and upper portion 62 of the partition 6 which surrounds the display element DE3.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

All of the sealing layers SE1, SE2 and SE3 extend to the upper side of the partition 6 and are spaced apart from the upper portion 62 of the partition 6. Thus, a void GP is defined between each of the sealing layers SE1, SE2 and SE3 and the upper portion 62. The end portions of the sealing layers SE1, SE2 and SE3 are spaced apart from the upper portion 62.

The end portions of the sealing layers SE1, SE2 and SE3 are located above the partition 6. In the example shown in the figure, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

A sealing layer SEL directly covers the sealing layers SE1, SE2 and SE3. The sealing layer SEL directly and continuously overlaps the sealing layers SE1, SE2 and SE3 immediately above the display elements DE1, DE2 and DE3 and the partition 6. In other words, no resin layer is interposed between the sealing layer SE1, SE2 or SE3 and the sealing layer SEL.

Further, the sealing layer SEL covers the end portion of each of the sealing layers SE1, SE2 and SE3. In other words, the end portions of the sealing layers SE1 and SE2 located above the partition 6 between subpixels SP1 and SP2 are spaced apart from each other, and the sealing layer SEL is provided such that the space of this separation is filled with the sealing layer SEL. Similarly, the end portions of the sealing layers SE1 and SE3 located above the partition 6 between subpixels SP1 and SP3 are spaced apart from each other, and the sealing layer SEL is provided such that the space of this separation is filled with the sealing layer SEL. Moreover, similarly, the end portions of the sealing layers SE1 and SE3 located above the partition 6 between subpixels SP1 and SP3 are spaced apart from each other, and the sealing layer SEL is provided such that the space of this separation is filled with the sealing layer SEL. Thus, the void GP is an airtight space which is surrounded by the upper portion 62, the sealing layers SE1, SE2 and SE3 and the sealing layer SEL and which does not communicate with the outside. For example, the void GP located between the display element DE1 and the display element DE2 is surrounded by the upper portion 62 of the partition 6, the sealing layers SE1 and SE2 and the sealing layer SEL.

A resin layer RL covers the sealing layer SEL. A cover plate CV or a polarizer POL is attached to the resin layer RL. The cover plate CV is a transparent glass substrate or a transparent resinous substrate. It should be noted that the polarizer POL may be attached to the resin layer RL and the cover plate CV may be attached to the polarizer POL.

Each of the insulating layer 5, the sealing layers SE1, SE2 and SE3 and the sealing layer SEL is formed of, for example, an inorganic insulating material such as silicon nitride (SiNx), silicon oxide (SiOx), silicon oxynitride (SiON) or aluminum oxide (Al₂O₃). For example, the insulating layer 5 is formed of silicon oxynitride, and each of the sealing layers SE1, SE2, SE3 and the sealing layer SEL is formed of silicon nitride.

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The stem layer 64 is formed of a material which is different from the materials of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The thin film 65 is formed of, for example, a titanium-based material such as titanium or a titanium compound. The thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and insulating layer 5 shown in the figure are provided over the display area DA and the surrounding area SA.

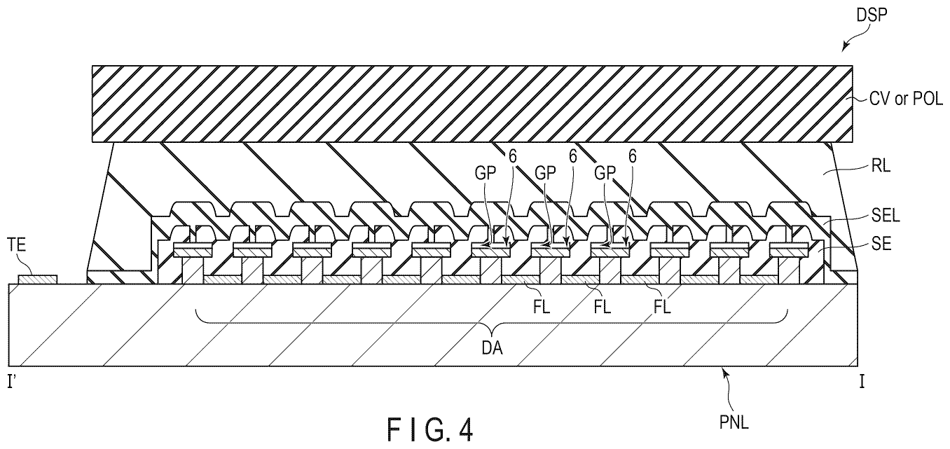

FIG. 4 is a schematic cross-sectional view showing a configuration example of the display device DSP along the I-I′ line of FIG. 1.

Here, the illustration of the display panel PNL is simplified. In the figure, the stacked films FL correspond to the stacked films FL1, FL2 and FL3 shown in FIG. 3, and the sealing layers SE correspond to the sealing layers SE1, SE2 and SE3 shown in FIG. 3. As described above, each sealing layer SE covers the stacked film FL and has an end portion immediately above the partition 6. The sealing layer SEL is continuously provided over the entire display area DA, covers the sealing layers SE and extends to the outside of the display area DA. The void GP is formed immediately above the partition 6. The resin layer RL is continuously provided over the entire display area DA and covers the sealing layer SEL. The cover plate CV or the polarizer POL is attached to the upper surface of the resin layer RL in the display area DA. The terminal TE is exposed from the sealing layer SEL and the resin layer RL. The end portion of the sealing layer SEL and the end portion of the resin layer RL are located between the terminal TE and the display area DA. In the example shown in the figure, the end portion of the resin layer RL overlaps the end portion of the sealing layer SEL.

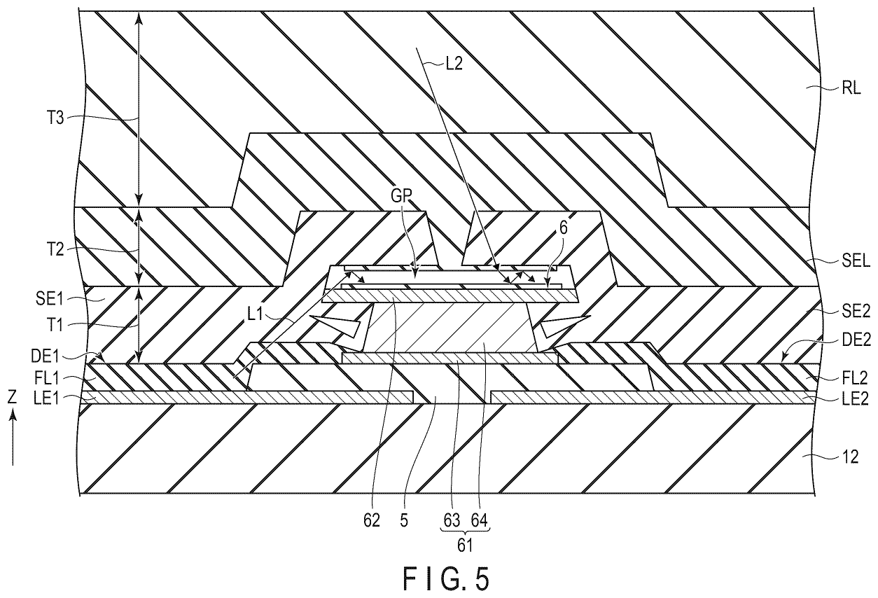

FIG. 5 is a cross-sectional view in which the void GP is enlarged.

Here, the figure shows the void GP formed between the display element DE1 and the display element DE2. In the example shown in the figure, the number of voids GP located immediately above the partition 6 is one. It should be noted that the sealing layer SEL between the sealing layer SE1 and the sealing layer SE2 could be formed so as to be in contact with the upper portion 62. In this case, the void located immediately above the partition 6 is divided into two voids, specifically, a void between the sealing layer SE1 and the upper portion 62 and a void between the sealing layer SE2 and the upper portion 62.

The sealing layer SE1 has thickness T1 which is equal to the thickness of the sealing layer SE2 in a third direction Z. The sealing layer SEL has thickness T2 in the third direction Z. To form a void GP which is closed by filling the gap between the sealing layer SE1 and the sealing layer SE2 with the sealing layer SEL, thickness T2 of the sealing layer SEL should be preferably greater than or equal to thickness T1 of the sealing layer SE1. For example, thickness T1 and thickness T2 are 2 to 3 μm.

The resin layer RL has thickness T3 in the third direction Z. Thickness T3 is greater than thickness T1 and thickness T2. For example, thickness T3 is approximately 10 μm.

In the configuration in which the void GP is formed immediately above the partition 6, the following effects are obtained.

When light L1 emitted from the display element DE1 or, of the incident light from the outside, light L1 reflected on the stacked film FL1 or the lower electrode LE1 proceeds to an adjacent subpixel, light L1 is trapped in the void GP as light L1 reaches the void GP, and thus, the degradation of the display quality can be prevented.

Further, when incident light L2 from the outside is reflected on the upper portion 62 of the partition 6, similarly, the reflected light L2 is trapped in the void GP, thereby preventing the degradation of the display quality to be caused by undesired reflected light.

Now, this specification explains a configuration example of the display element DE.

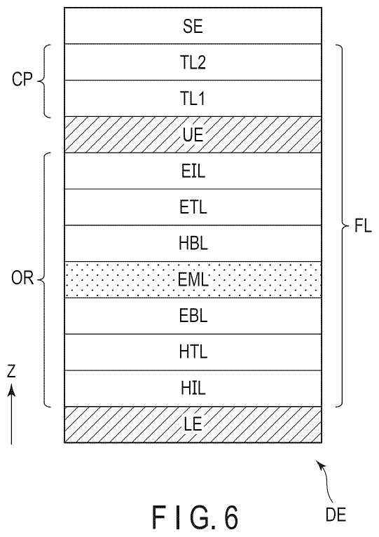

FIG. 6 is a diagram showing a configuration example of the display element DE.

The display element DE shown in the figure may correspond to all of the display elements DE1, DE2 and DE3 described above.

Here, this specification explains an example in which a lower electrode LE corresponds to an anode and an upper electrode UE corresponds to a cathode.

The display element DE comprises an organic layer OR (OR1, OR2 or OR3) between the lower electrode LE (LE1, LE2 or LE3) and the upper electrode UE (UE1, UE2 or UE3).

In the organic layer OR, a hole injection layer HIL, a hole transport layer HTL, an electron blocking layer EBL, a light emitting layer EML, a hole blocking layer HBL, an electron transport layer ETL and an electron injection layer EIL are stacked in this order in the third direction Z.

It should be noted that the organic layer OR may include, in addition to the functional layers described above, other functional layers such as a carrier generation layer as needed, or at least one of the above functional layers may be omitted.

The light emitting layer EML corresponds to one of the light emitting layers EM1, EM2 and EM3 shown in FIG. 3.

A cap layer CP (CP1, CP2 or CP3) includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2.

It should be noted that the configuration of the organic layer OR is not limited to the configuration in which the organic layer OR comprises the light emitting layer EML consisting of a single layer as shown in the figure. The organic layer OR may comprise a tandem configuration comprising a plurality of light emitting layers.

Now, this specification explains the outline of a device for manufacturing the display device DSP.

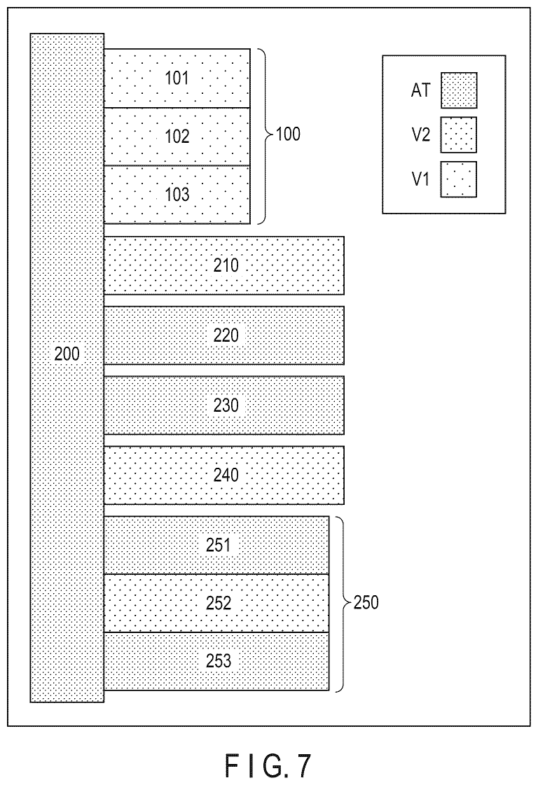

FIG. 7 is a diagram for explaining the outline of a manufacturing device.

In the figure, the dotted patterns indicate the atmosphere of each device. The nondensest dotted pattern V1 indicates a high vacuum environment having a first degree of vacuum. The densest dotted pattern AT indicates an air atmosphere. Dotted pattern V2 having a density between dotted pattern V1 and dotted pattern AT indicates a vacuum environment having a second degree of vacuum which is lower than the first degree of vacuum.

A plurality of processing substrates are accommodated in a substrate compartment 200 in an air atmosphere. Here, each processing substrate is a mother substrate for display devices and comprises a plurality of panel portions on a large substrate. Each panel portion is extracted by dividing each processing substrate. Each of the extracted panel portions corresponds to the display panel PNL shown in FIG. 1 and comprises the display area DA and the surrounding area SA.

An in-line evaporation device 100 comprises a preprocessing portion 101, a heating portion 102 and an evaporation portion 103. The evaporation device 100 is configured to form an evaporation layer on a processing substrate in a high vacuum environment having the first degree of vacuum as described later.

A chemical vapor deposition (CVD) device 210 is configured to form the sealing layers SE1, SE2 and SE3 and the sealing layer SEL by depositing an inorganic insulating material on a processing substrate in a vacuum environment having the second degree of vacuum.

A resist formation device 220 is configured to form a resist having a predetermined shape on the sealing layers SE1, SE2 and SE3 in an air atmosphere.

A wet etching device 230 is configured to remove part of the stacked films FL1, FL2 and FL3 using a resist as a mask in an air atmosphere.

A dry etching device 240 is configured to remove part of the stacked films FL1, FL2 and FL3, part of the sealing layers SE1, SE2 and SE3 and part of the sealing layer SEL using a resist as a mask in a vacuum environment having the second degree of vacuum.

A resin formation device 250 is configured to form the resin layer RL. The resin formation device 250 comprises an application device 251, a drying device 252 and a curing device 253. The application device 251 is configured to apply a resinous material in an air atmosphere. The drying device 252 is configured to dry a resinous material in a low vacuum environment (the second degree of vacuum) where the pressure is reduced compared to an air atmosphere. It should be noted that the drying device 252 may be omitted. The curing device 253 is configured to perform the curing process of a resinous material in an air atmosphere. For example, when the resinous material is an ultraviolet curing resinous material, the curing device 253 is configured to irradiate the resinous material with ultraviolet rays.

Each of the evaporation device 100, the CVD device 210, the resist formation device 220, the wet etching device 230, the dry etching device 240 and the resin formation device 250 is connected to the substrate compartment 200 via a conveyance mechanism which is not described in detail.

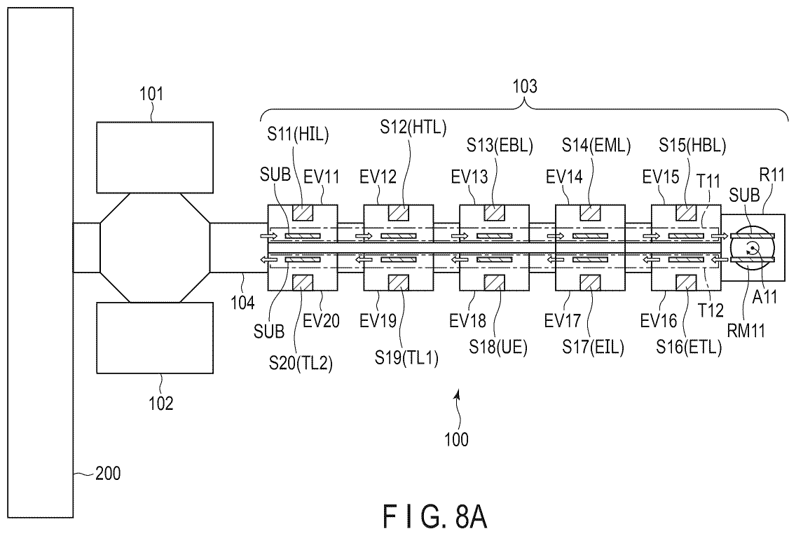

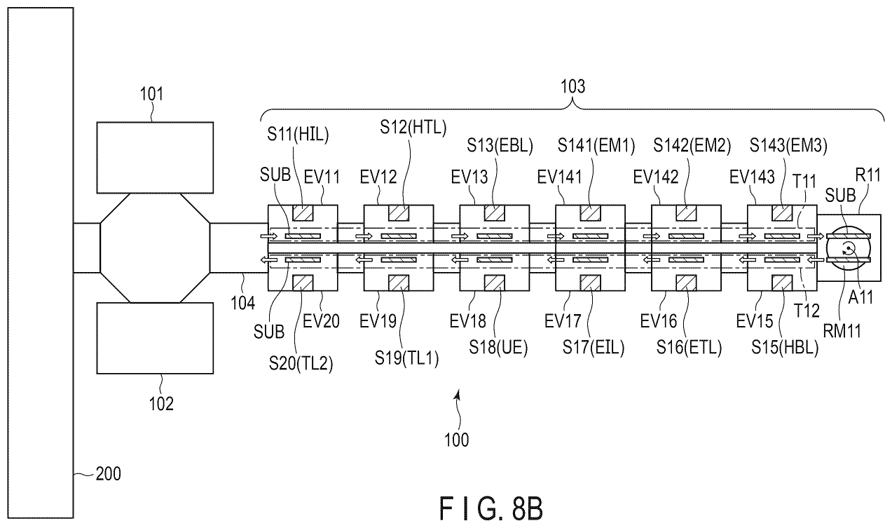

FIG. 8A is a diagram showing a configuration example of the evaporation device 100 shown in FIG. 7.

For example, the evaporation device 100 is applied in the process of successively forming the organic layer OR, upper electrode UE and cap layer CP shown in FIG. 6. A processing substrate SUB which is supposed to be carried in the evaporation device 100 comprises the circuit layer 11, the insulating layer 12, the lower electrodes LE1, LE2 and LE3, the insulating layer 5 and the partition 6 on the substrate 10.

The evaporation device 100 comprises the preprocessing portion 101, the heating portion 102 and the evaporation portion 103. Although not described in detail, the evaporation device 100 is connected to the substrate compartment 200 via a conveyance mechanism. The evaporation device 100 comprises a posture change portion 104 as part of the conveyance mechanism.

The preprocessing portion 101 comprises a mechanism which performs various preprocesses such as a plasma process for the processing substrate SUB which was carried in. The heating portion 102 comprises a mechanism which performs a heating process for the processing substrate SUB.

The posture change portion 104 comprises a mechanism which changes the posture of the processing substrate SUB, a mechanism which secures the processing substrate SUB to a dedicated carrier by an electrostatic chuck, a mechanism which detaches the processing substrate SUB from the carrier by releasing the securing applied by the electrostatic chuck, etc. For example, the posture of the processing substrate SUB which is carried in the preprocessing portion 101 and the heating portion 102 is a horizontal posture. The posture of the processing substrate SUB which was carried out of the preprocessing portion 101 and the heating portion 102 is changed from a horizontal posture to a perpendicular posture in the posture change portion 104. The posture of the processing substrate SUB which is carried in the evaporation portion 103 is a perpendicular posture. The posture of the processing substrate SUB which was carried out of the evaporation portion 103 is changed from a perpendicular posture to a horizontal posture in the posture change portion 104.

The evaporation portion 103 comprises a plurality of evaporation chambers EV11 to EV20 and a rotation chamber R11. The preprocessing portion 101, the heating portion 102, the posture change portion 104, the evaporation chambers EV11 to EV20 and the rotation chamber R11 are connected to each other and are maintained as a high vacuum (the first degree of vacuum).

The evaporation chambers EV11 to EV15 are arranged in line. The evaporation chamber EV11 is connected to the posture change portion 104. The evaporation chamber EV15 is connected to the rotation chamber R11. A conveyance path T11 is provided over the evaporation chambers EV11 to EV15.

The evaporation chambers EV16 to EV20 are arranged in line. The evaporation chamber EV16 is connected to the rotation chamber R11. The evaporation chamber EV20 is connected to the posture change portion 104. A conveyance path T12 is provided over the evaporation chambers EV16 to EV20.

The evaporation chamber EV11 comprises an evaporation source S11. The evaporation source S11 is configured to emit a material for forming the hole injection layer HIL toward the conveyance path T11.

The evaporation chamber EV12 comprises an evaporation source S12. The evaporation source S12 is configured to emit a material for forming the hole transport layer HTL toward the conveyance path T11.

The evaporation chamber EV13 comprises an evaporation source S13. The evaporation source S13 is configured to emit a material for forming the electron blocking layer EBL toward the conveyance path T11.

The evaporation chamber EV14 comprises an evaporation source S14. The evaporation source S14 is configured to emit a material for forming the light emitting layer EML toward the conveyance path T11. The light emitting layer EML described here is one of the light emitting layers EM1, EM2 and EM3 shown in FIG. 3.

The evaporation chamber EV15 comprises an evaporation source S15. The evaporation source S15 is configured to emit a material for forming the hole blocking layer HBL toward the conveyance path T11.

The evaporation chamber EV16 comprises an evaporation source S16. The evaporation source S16 is configured to emit a material for forming the electron transport layer ETL toward the conveyance path T12.

The evaporation chamber EV17 comprises an evaporation source S17. The evaporation source S17 is configured to emit a material for forming the electron injection layer EIL toward the conveyance path T12.

The evaporation chamber EV18 comprises an evaporation source S18. The evaporation source S18 is configured to emit a material for forming the upper electrode UE toward the conveyance path T12.

The evaporation chamber EV19 comprises an evaporation source S19. The evaporation source S19 is configured to emit a material for forming the first transparent layer TL1 toward the conveyance path T12.

The evaporation chamber EV20 comprises an evaporation source S20. The evaporation source S20 is configured to emit a material for forming the second transparent layer TL2 toward the conveyance path T12.

The rotation chamber R11 is configured to convey the processing substrate SUB which is carried out of the conveyance path T11 to the conveyance path T12. The rotation chamber R11 comprises a rotation mechanism RM11. The rotation mechanism RM11 is configured to hold the processing substrate SUB which is carried in the rotation chamber R11 via the conveyance path T11 and rotate around a rotation axis A11.

It should be noted that the configuration of the evaporation device 100 is not limited to the example shown in the figure.

FIG. 8B is a diagram showing another configuration example of the evaporation device 100 shown in FIG. 7.

The configuration example shown in FIG. 8B is different from that shown in FIG. 8A in respect that an evaporation chamber for forming each of the light emitting layers EM1, EM2 and EM3 is provided.

In the evaporation portion 103 of the evaporation device 100, the evaporation chambers EV11, EV12, EV13, EV141, EV142 and EV143 are arranged in line. The evaporation chamber EV11 is connected to the posture change portion 104. The evaporation chamber EV143 is connected to the rotation chamber R11.

The evaporation chambers EV15 to EV20 are arranged in line. The evaporation chamber EV15 is connected to the rotation chamber R11. The evaporation chamber EV20 is connected to the posture change portion 104.

The evaporation source S11 of the evaporation chamber EV11 is configured to emit a material for forming the hole injection layer HIL.

The evaporation source S12 of the evaporation chamber EV12 is configured to emit a material for forming the hole transport layer HTL.

The evaporation source S13 of the evaporation chamber EV13 is configured to emit a material for forming the electron blocking layer EBL.

The evaporation source S141 of the evaporation chamber EV141 is configured to emit a material for forming the light emitting layer EM1.

The evaporation source S142 of the evaporation chamber EV142 is configured to emit a material for forming the light emitting layer EM2.

The evaporation source S143 of the evaporation chamber EV143 is configured to emit a material for forming the light emitting layer EM3.

The materials emitted from the evaporation sources S141, S142 and S143 are light emitting materials which emit different colors.

The evaporation source S15 of the evaporation chamber EV15 is configured to emit a material for forming the hole blocking layer HBL.

The evaporation source S16 of the evaporation chamber EV16 is configured to emit a material for forming the electron transport layer ETL.

The evaporation source S17 of the evaporation chamber EV17 is configured to emit a material for forming the electron injection layer EIL.

The evaporation source S18 of the evaporation chamber EV18 is configured to emit a material for forming the upper electrode UE.

The evaporation source S19 of the evaporation chamber EV19 is configured to emit a material for forming the first transparent layer TL1.

The evaporation source S20 of the evaporation chamber EV20 is configured to emit a material for forming the second transparent layer TL2.

When the display element DE1 is formed in this evaporation device 100, the materials are deposited in series in the evaporation chambers EV11, EV12, EV13 and EV141 while the processing substrate SUB is conveyed in a perpendicular posture. Subsequently, the processing substrate SUB is conveyed without the deposition of the materials in the evaporation chambers EV142 and EV143. Subsequently, the materials are deposited in series in the evaporation chambers EV15 to EV20.

When the display element DE2 is formed, the materials are deposited in series in the evaporation chambers EV11, EV12 and EV13 while the processing substrate SUB is conveyed in a perpendicular posture. Subsequently, the processing substrate SUB is conveyed without the deposition of the material in the evaporation chamber EV141. Subsequently, the material is deposited in the evaporation chamber EV142. Subsequently, the processing substrate SUB is conveyed without the deposition of the material in the evaporation chamber EV143. Subsequently, the materials are deposited in series in the evaporation chambers EV15 to EV20.

When the display element DE3 is formed, the materials are deposited in series in the evaporation chambers EV11, EV12 and EV13 while the processing substrate SUB is conveyed in a perpendicular posture. Subsequently, the processing substrate SUB is conveyed without the deposition of the materials in the evaporation chambers EV141 and EV142. Subsequently, the materials are deposited in series in the evaporation chambers EV143 and EV15 to EV20.

In each of the configuration examples shown in FIG. 8A and FIG. 8B, the evaporation portion 103 comprises the rotation chamber R11 and is configured to turn back the processing substrate SUB. However, the configuration is not limited to this example.

The evaporation portion 103 may be configured to convey the processing substrate SUB in a single direction by omitting the rotation chamber R11. In this case, for example, in the configuration example shown in FIG. 8A, the evaporation chambers EV11, EV12, EV13, EV14, EV15, EV16, EV17, EV18, EV19 and EV20 are arranged in this order in a single direction. In the configuration example shown in FIG. 8B, the evaporation chambers EV11, EV12, EV13, EV141, EV142, EV143, EV15, EV16, EV17, EV18, EV19 and EV20 are arranged in this order in a single direction.

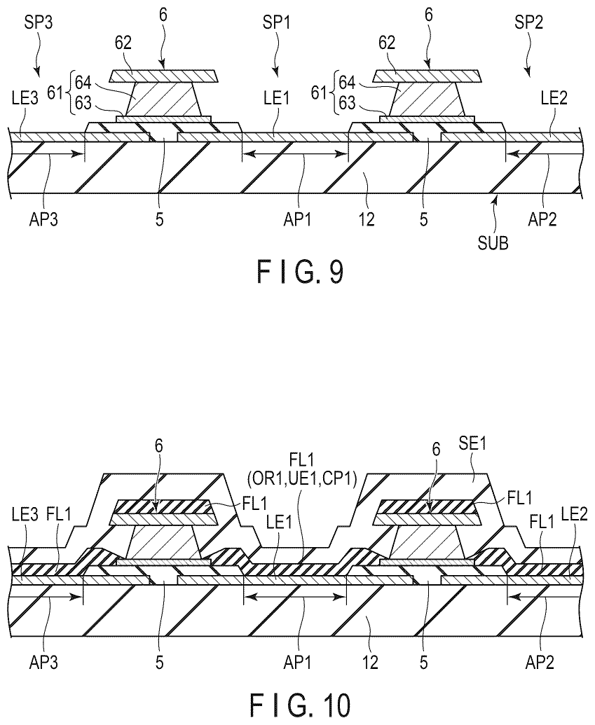

Now, this specification explains the manufacturing method of the display device DSP. In FIG. 9 to FIG. 14, the illustration of the lower side of the insulating layer 12 is omitted.

First, as shown in FIG. 9, a processing substrate SUB is prepared. The process of preparing the processing substrate SUB includes the process of forming the lower electrode LE1 of subpixel SP1, the lower electrode LE2 of subpixel SP2 and the lower electrode LE3 of subpixel SP3 on the insulating layer 12, the process of forming the insulating layer 5 having the apertures AP1, AP2 and AP3 overlapping the lower electrodes LE1, LE2 and LE3, respectively, and the process of forming the partition 6 having the lower portion 61 located on the insulating layer 5 and the upper portion 62 located on the lower portion 61 and protruding from the side surfaces of the lower portion 61 on the insulating layer 5. It should be noted that the partition 6 may be formed after the formation of the insulating layer 5 having the apertures AP1, AP2 and AP3, or the apertures AP1, AP2 and AP3 may be formed after the formation of the partition 6.

Subsequently, the display element DE1 is formed.

First, for example, the processing substrate SUB is carried in the evaporation device 100 shown in FIG. 8A, and a predetermined preprocess is performed for the processing substrate SUB in the preprocessing portion 101. Subsequently, a heating process is performed for the processing substrate SUB in the heating portion 102 depending on the need. The processing substrate SUB is changed to a perpendicular posture in the posture change portion 104. The processing substrate SUB is carried in the evaporation portion 103.

Subsequently, the stacked film FL1 is formed on the processing substrate SUB by performing vapor deposition using the partition 6 as a mask in the evaporation portion 103. Specifically, the hole injection layer HIL is formed on the lower electrode LE1 in the evaporation chamber EV11. The hole transport layer HTL is formed on the hole injection layer HIL in the evaporation chamber EV12. The electron blocking layer EBL is formed on the hole transport layer HTL in the evaporation chamber EV13. The light emitting layer EM1 is formed on the electron blocking layer EBL in the evaporation chamber EV14. The hole blocking layer HBL is formed on the light emitting layer EM1 in the evaporation chamber EV15. The electron transport layer ETL is formed on the hole blocking layer HBL in the evaporation chamber EV16. The electron injection layer EIL is formed on the electron transport layer ETL in the evaporation chamber EV17. By this process, the organic layer OR1 including the light emitting layer EM1 is formed on the lower electrode LE1. Subsequently, the upper electrode UE is formed on the electron injection layer EIL in the evaporation chamber EV18. By this process, the upper electrode UE1 is formed on the organic layer OR1. Subsequently, the first transparent layer TL1 is formed on the upper electrode UE in the evaporation chamber EV19. The second transparent layer TL2 is formed on the first transparent layer TL1 in the evaporation chamber EV20. By this process, the cap layer CP1 is formed on the upper electrode UE1.

The organic layer OR1, upper electrode UE1 and cap layer CP1 included in the stacked film FL1 are successively formed using the partition 6 as a mask in a vacuum environment having the first degree of vacuum in the evaporation device 100 (evaporation process). Subsequently, as shown in FIG. 10, the sealing layer SE1 is formed on the stacked film FL1. Specifically, the processing substrate SUB is carried out of the evaporation portion 103. The processing substrate SUB is changed to a horizontal posture in the posture change portion 104. The processing substrate SUB is carried in the CVD device 210 having the second degree of vacuum. An inorganic insulating material (for example, silicon nitride) is deposited on the processing substrate SUB in the CVD device 210. By this process, the sealing layer SE1 which continuously covers the stacked film FL1 and the partition 6 is formed.

The stacked film FL1 and the sealing layer SE1 are formed in at least the entire display area DA and are provided in subpixels SP2 and SP3 as well as subpixel SP1. The stacked film FL1 is divided by the partition 6 having an overhang shape.

The materials which are emitted from the evaporation sources when the organic layer OR1, the upper electrode UE1 and the cap layer CP1 constituting the stacked film FL1 are formed by vapor deposition are blocked by the upper portion 62. For this reason, part of the stacked film FL1 is stacked on the upper portion 62. The stacked film FL1 located on the upper portion 62 is spaced apart from the stacked film FL1 located immediately above the lower electrode LE1.

The sealing layer SE1 covers the stacked film FL1 located immediately above the partition 6, covers the stacked film FL1 located immediately above the lower electrode LE1 and is in contact with the partition 6.

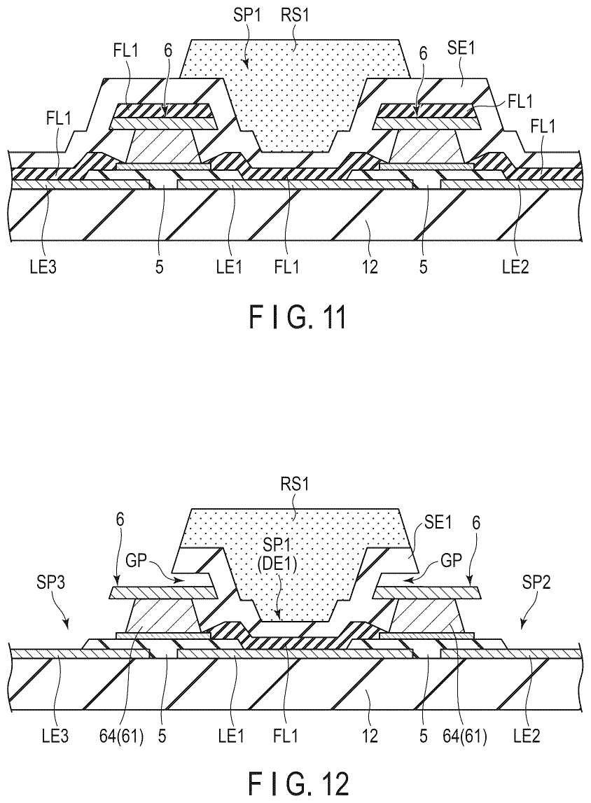

Subsequently, as shown in FIG. 11, a resist RS1 patterned into a predetermined shape is formed on the sealing layer SE1. The resist RS1 is formed in the resist formation device 220. The resist RS1 overlaps subpixel SP1 and part of the partition 6 around subpixel SP1.

Subsequently, as shown in FIG. 12, the sealing layer SE1 and the stacked film FL1 are patterned using the resist RS1 as a mask. The patterning is performed in the wet etching device 230 and the dry etching device 240. The sealing layer SE1 and the stacked film FL1 (the cap layer CP1, the upper electrode UE1 and the organic layer OR1) exposed from the resist RS1 are removed in series by performing various types of etching using the resist RS1 as a mask.

By this patterning, the lower electrode LE2 of subpixel SP2 and the lower electrode LE3 of subpixel SP3 are exposed.

Subsequently, the resist RS1 is removed. By this process, the display element DE1 is formed in subpixel SP1. In the example shown in the figure, the stacked film FL1 located on the partition 6 is removed during the process of patterning the stacked film FL1 and removing the resist RS1. Therefore, the void GP is formed between the sealing layer SE1 and the partition 6.

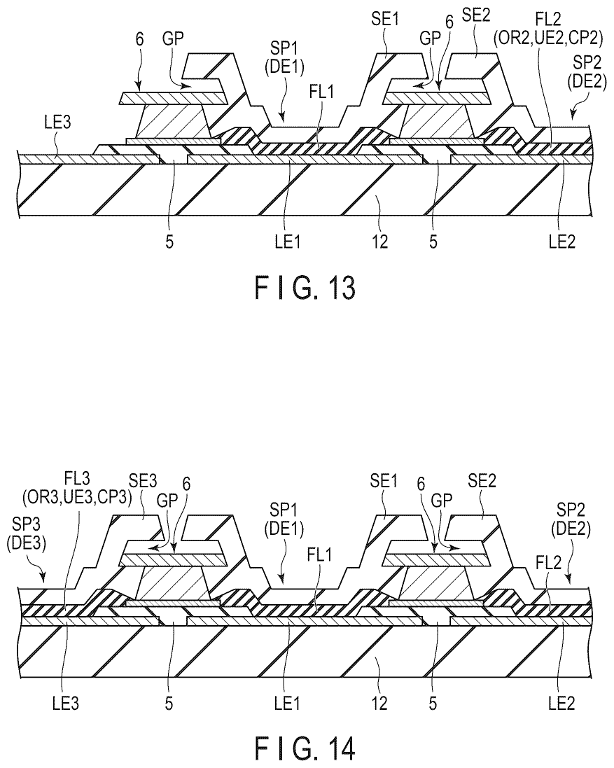

Subsequently, as shown in FIG. 13, the display element DE2 is formed. The procedure of forming the display element DE2 is similar to that of forming the display element DE1. Specifically, the preprocess of the processing substrate SUB in which the display element DE1 is formed is performed. Subsequently, the stacked film FL2 is formed on the lower electrode LE2. The stacked film FL2 has the organic layer OR2 including the light emitting layer EM2, the upper electrode UE2 and the cap layer CP2. Subsequently, the sealing layer SE2 is formed. Subsequently, a resist is formed on the sealing layer SE2. Subsequently, patterning is performed using the resist as a mask. By this process, the sealing layer SE2 and stacked film FL2 exposed from the resist are removed in series. Subsequently, the resist is removed.

In this manner, the display element DE2 is formed in subpixel SP2, and the lower electrode LE3 of subpixel SP3 is exposed. In the example shown in the figure, as the stacked film FL2 located on the partition 6 is removed at the time of patterning, the void GP is defined between the sealing layer SE2 and the partition 6.

Subsequently, as shown in FIG. 14, the display element DE3 is formed. The procedure of forming the display element DE3 is similar to that of forming the display element DE1. Specifically, the preprocess of the processing substrate SUB in which the display element DE1 and the display element DE2 are formed is performed. Subsequently, the stacked film FL3 is formed on the lower electrode LE3. The stacked film FL3 has the organic layer OR3 including the light emitting layer EM3, the upper electrode UE3 and the cap layer CP3. Subsequently, the sealing layer SE3 is formed. Subsequently, a resist is formed on the sealing layer SE3. Subsequently, patterning is performed using the resist as a mask. By this process, the sealing layer SE3 and the stacked film FL3 exposed from the resist are removed in series. Subsequently, the resist is removed.

By this process, the display element DE3 is formed in subpixel SP3. In the example shown in the figure, as the stacked film FL3 located on the partition 6 is removed at the time of patterning, the void GP is defined between the sealing layer SE3 and the partition 6.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

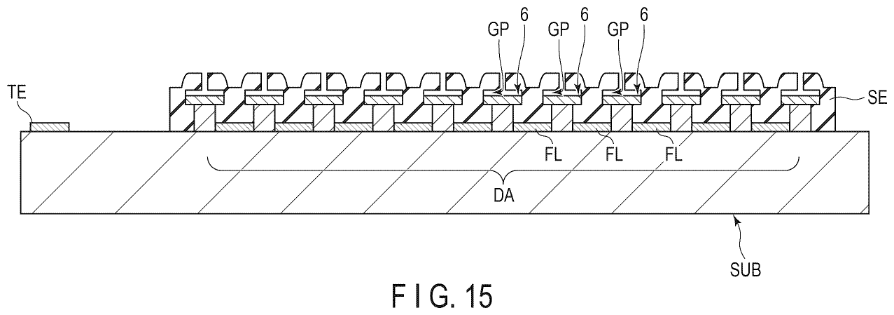

The processing substrate SUB in which the display elements DE1, DE2 and DE3 are formed in this manner is conveyed to an environment under an air atmosphere as shown in FIG. 15. Each stacked film FL is sealed with the sealing layer SE. The terminal TE is formed in the process of forming the circuit layer 11.

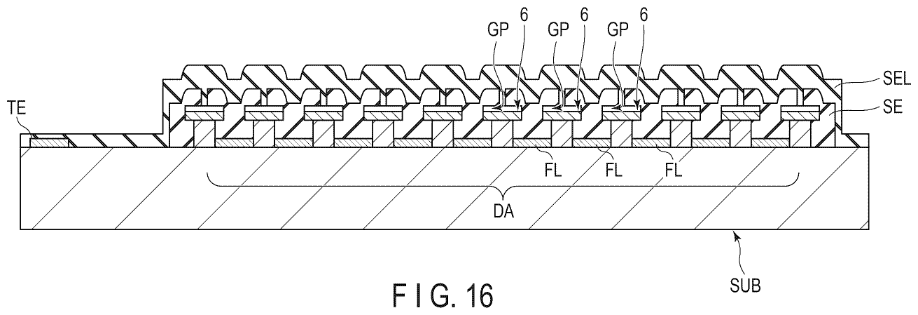

Subsequently, as shown in FIG. 16, the sealing layer SEL is formed on the whole surface of the processing substrate SUB. Specifically, the processing substrate SUB is carried in the CVD device 210 having the second degree of vacuum. An inorganic insulating material (for example, silicon nitride) is deposited in the CVD device 210. By this process, the sealing layer SEL which directly covers each of the sealing layers SE1, SE2 and SE3 and covers the terminal TE is formed. At this time, the void GP is present immediately above the partition 6. The void GP is surrounded by the upper portion 62, the sealing layers SE1, SE2 and SE3 and the sealing layer SEL.

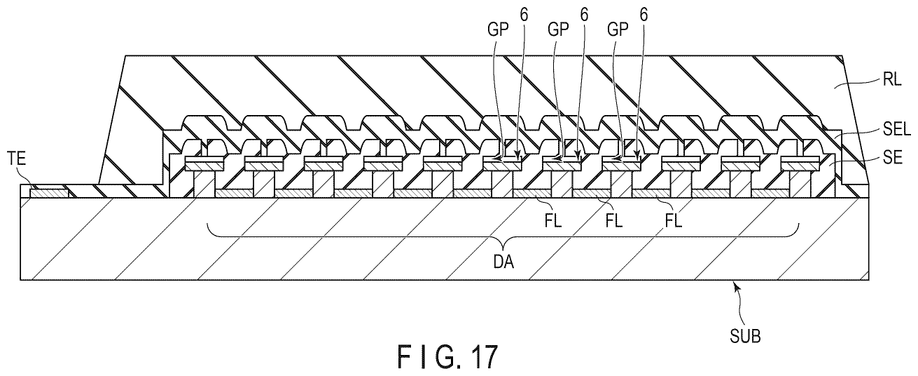

Subsequently, as shown in FIG. 17, the resin layer RL is formed over the entire display area DA. Specifically, first, the processing substrate SUB is carried in the application device 251 of the resin formation device 250. In the application device 251, a resinous material is applied to the upper side of sealing layer SEL in an air atmosphere. At this time, the resinous material is applied so as not to overlap the terminal TE.

Subsequently, the processing substrate SUB is carried in the drying device 252. The drying device 252 is maintained such that the pressure is lower than an air atmosphere. As the processing substrate SUB is placed in the decompressed environment, the emission of moisture from the resinous material is accelerated, and the resinous material is dried.

Subsequently, the processing substrate SUB is carried in the curing device 253. In the curing device 253, for example, the resinous material is irradiated with ultraviolet rays in an air atmosphere. By the irradiation, the resinous material is cured. By this process, the resin layer RL is formed on the sealing layer SEL. However, the resin layer RL does not overlap the terminal TE. It should be noted that, after the resinous material is applied, the resinous material may be irradiated with ultraviolet rays by skipping the drying process.

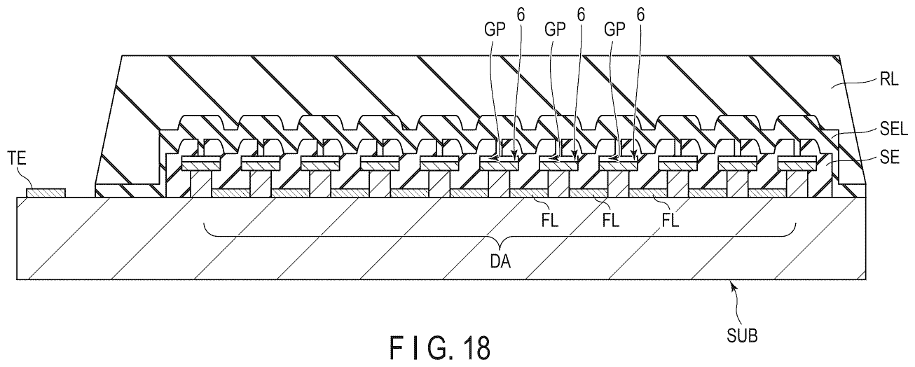

Subsequently, as shown in FIG. 18, the sealing layer SEL is patterned using the resin layer RL as a mask. Specifically, the processing substrate SUB is carried in the dry etching device 240. In the dry etching device 240, the sealing layer SEL is removed by etching using the resin layer RL as a mask in a vacuum environment having the second degree of vacuum. In this manner, the end portion of the resin layer RL overlaps the end portion of the sealing layer SEL. By this patterning of the sealing layer SEL, the terminal TE is exposed from the sealing layer SEL.

Subsequently, the cover plate CV or the polarizer POL is attached to the upper surface of the resin layer RL.

Through the above process, the display device DSP is completed.

Now, this specification explains another manufacturing method of the display device DSP.

This manufacturing method is the same as that explained earlier from the process of preparing the processing substrate SUB shown in FIG. 9 to the process of forming the sealing layer SEL shown in FIG. 16.

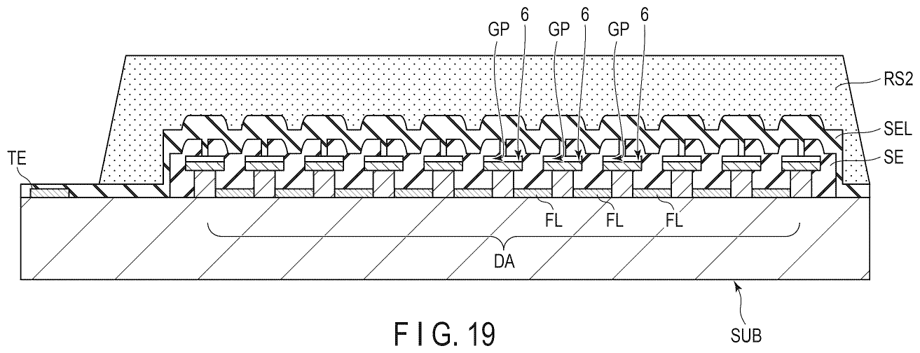

After the sealing layer SEL is formed, as shown in FIG. 19, a resist RS2 is formed on the sealing layer SEL over the entire display area DA. This resist RS2 can be formed through, for example, a process similar to that of the resin layer RL explained with reference to FIG. 17. The resist RS2 overlaps the display area DA and does not overlap the terminal TE.

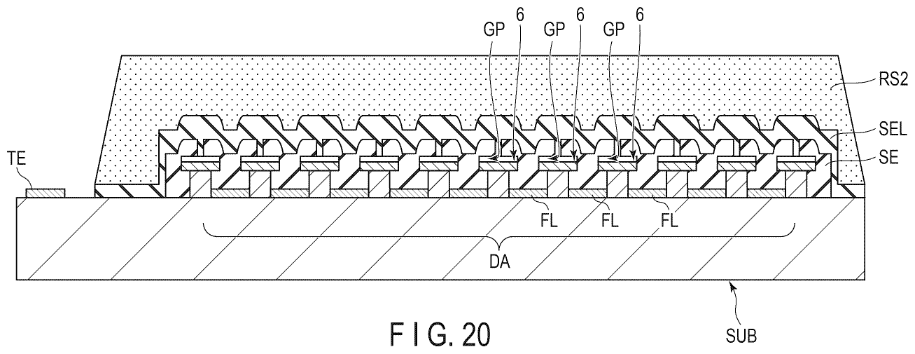

Subsequently, as shown in FIG. 20, the sealing layer SEL is patterned using the resist RS2 as a mask. Specifically, the processing substrate SUB is carried in the dry etching device 240. In the dry etching device 240, the sealing layer SEL is removed by etching using the resist RS2 as a mask in a vacuum environment having the second degree of vacuum. By the patterning of the sealing layer SEL, the terminal TE is exposed from the sealing layer SEL. Subsequently, the resist RS2 is removed.

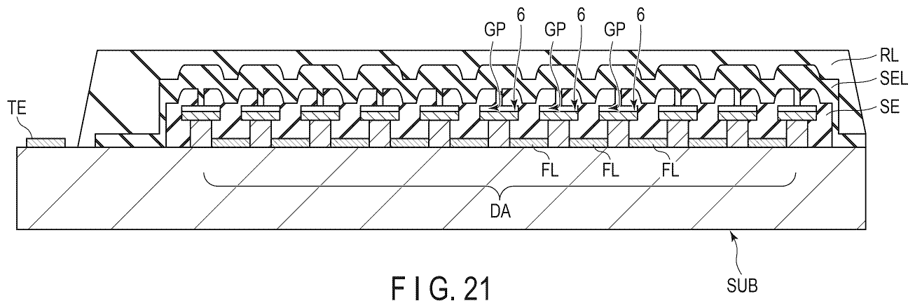

Subsequently, as shown in FIG. 21, the resin layer RL is formed over the entire display area DA. This resin layer RL can be formed through a process similar to that of the resin layer RL explained with reference to FIG. 17. It should be noted that the resin layer RL is not used as the mask of dry etching in the example shown in FIG. 21. In other words, in the example shown in FIG. 17, as the resin layer RL is used as the mask of dry etching, it is necessary to form the resin layer RL so as to be relatively thick. To the contrary, in the example shown in FIG. 21, the thickness of the resin layer RL can be reduced compared to the example shown in FIG. 17. In this manner, the thickness of the display device DSP can be reduced.

Further, in the example shown in FIG. 21, as the resin layer RL is formed on the patterned sealing layer SEL, the end portion of the resin layer RL does not necessarily overlap the end portion of the sealing layer SEL. Both the end portion of the resin layer RL and the end portion of the sealing layer SEL are located between the display area DA and the terminal TE while the end portion of the resin layer RL is located between the end portion of the sealing layer SEL and the terminal TE in the example shown in the figure.

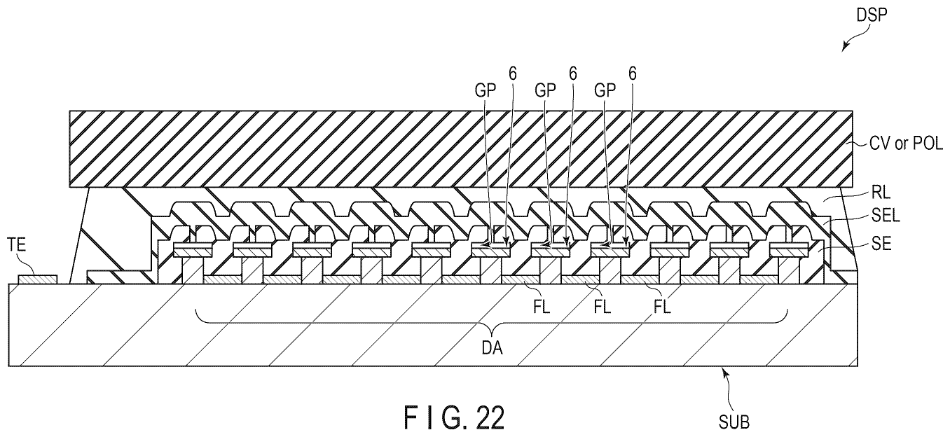

Subsequently, as shown in FIG. 22, the cover plate CV or the polarizer POL is attached to the upper surface of the resin layer RL.

Through the above process, the display device DSP is completed.

Now, another configuration example is explained.

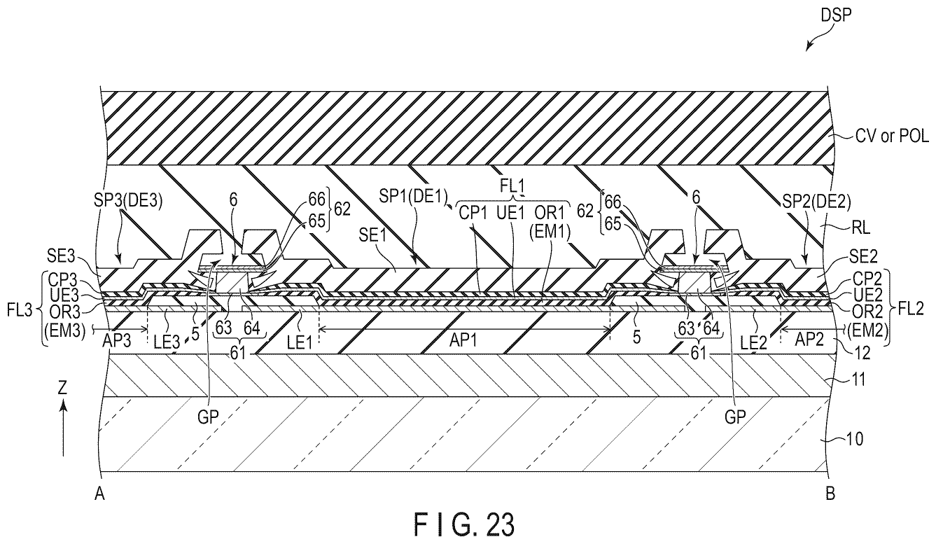

FIG. 23 is a schematic cross-sectional view showing another configuration example of the display device DSP along the A-B line of FIG. 2.

The configuration example shown in FIG. 23 is different from that shown in FIG. 3 in respect that the sealing layer SEL is omitted. The void GP is surrounded by each of the sealing layers SE1, SE2 and SE3 and the upper portion 62. The resin layer RL directly covers each of the sealing layers SE1, SE2 and SE3. The void GP is filled with the resin layer RL. The cover plate CV or the polarizer POL is attached to the upper surface of the resin layer RL.

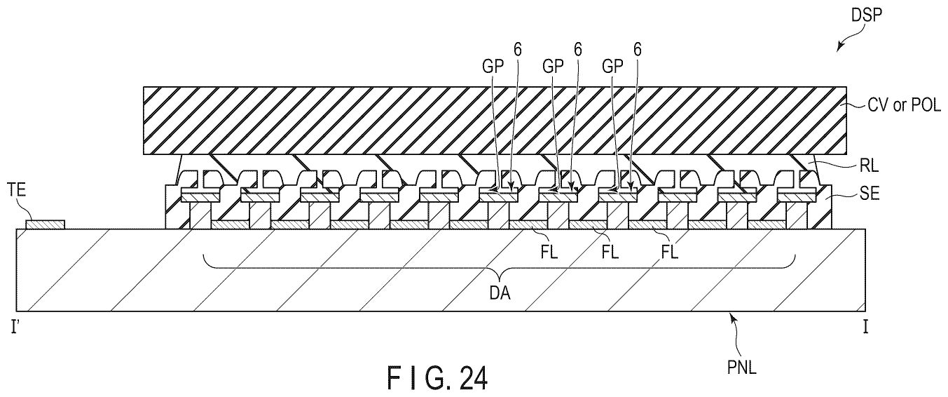

FIG. 24 is a schematic cross-sectional view showing another configuration example of the display device DSP along the I-I′ line of FIG. 1.

The configuration example shown in FIG. 24 is different from that shown in FIG. 4 in respect that the sealing layer SEL is omitted. The resin layer RL is continuously provided over the entire display area DA. The resin layer RL is not covered with any inorganic insulating layer. The cover plate CV or the polarizer POL is attached to the upper surface of the resin layer RL in the display area DA. The terminal TE is exposed from the resin layer RL. In the example shown in the figure, the end portion of the resin layer RL overlaps the sealing layer SE.

Now, this specification explains the manufacturing method of the display device DSP shown in FIG. 23 and FIG. 24.

This manufacturing method is the same as that explained earlier from the process of preparing the processing substrate SUB shown in FIG. 9 to the process of forming the display element DE3 shown in FIG. 14.

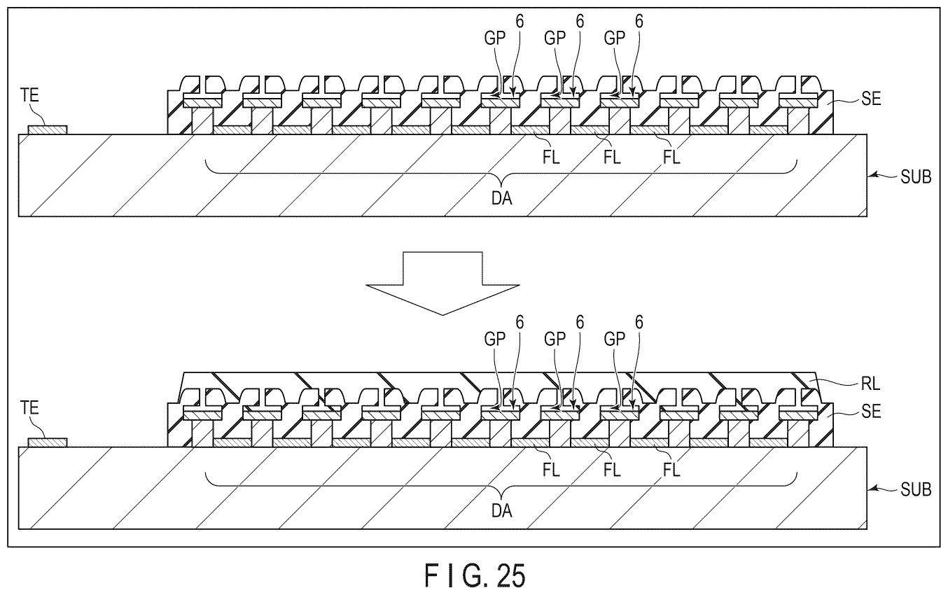

The processing substrate SUB in which the display elements DE1, DE2 and DE3 are formed in this manner is conveyed to an environment under an air atmosphere as shown in the upper part of FIG. 25. Each stacked film FL is sealed with the sealing layer SE. The terminal TE is formed in the process of forming the circuit layer 11.

Subsequently, as shown in the lower part of FIG. 25, the resin layer RL is formed over the entire display area DA. This resin layer RL can be formed through a process similar to that of the resin layer RL explained with reference to FIG. 17.

It should be noted that, as the sealing layer SEL is omitted in the example shown in FIG. 25, the resin layer RL is not used as the mask of dry etching. For this reason, in the example shown in FIG. 25, the thickness of the resin layer RL can be reduced compared to the example shown in FIG. 17. In this manner, the thickness of the display device DSP can be reduced.

Subsequently, the cover plate CV or the polarizer POL is attached to the upper surface of the resin layer RL.

Through the above process, the display device DSP is completed.

In the embodiment, the partition 6 is provided in the boundaries of subpixels SP1, SP2 and SP3. This partition 6 surrounds the organic layers OR1, OR2 and OR3, upper electrodes UE1, UE2 and UE3 and cap layers CP1, CP2 and CP3 formed by vapor deposition. The display element DE1 of subpixel SP1, the display element DE2 of subpixel SP2 and the display element DE3 of subpixel SP3 are individually divided from each other by the partition 6. These divided display elements DE1, DE2 and DE3 are individually sealed with the sealing layers SE1, SE2 and SE3, respectively. Thus, even if a problem occurs in one of the display elements because of permeation of moisture, the diffusion of the moisture which permeated the display element to an adjacent display element is prevented.

In addition, in the structure which prevents the diffusion of moisture to an adjacent display element as described above, the tolerable moisture content of the resin layer RL can be increased compared to a structure in which an organic layer is not divided in adjacent display elements (comparative example).

In the comparative example, when, for example, a crack is generated in a sealing layer, the moisture which entered the display element through the crack spreads over a plurality of display elements, and thus, a large number of display elements are damaged. For this reason, the moisture content should be very low regarding a resin layer which covers the sealing layer. Thus, the resin layer needs to be formed in a nitrogen atmosphere where the moisture concentration is very low or in an atmosphere of clean dry air. Thus, in the comparative example, equipment for generating a nitrogen atmosphere or clean dry air is needed.

In the embodiment, a high moisture content is allowed for the resin layer RL provided on the sealing layer SEL or the resin layer RL provided on the sealing layers SE1, SE2 and SE3. Therefore, the process of applying a resinous material to form the resin layer RL can be performed in an air atmosphere. For example, the process of applying a resinous material can be performed in an air atmosphere of a clean room which is adjusted such that the temperature is in the range of 20° C. to 30° C., the humidity is in the range of 40% to 70%, and the oxygen concentration is greater than equal to 20%. Thus, equipment for generating an atmosphere in which the moisture concentration is very low is unnecessary.

In addition, compared to the comparative example in which the resin layer is provided between the sealing layers SE1, SE2 and SE3 and the sealing layer SEL, the manufacturing process can be simplified, and thus, the manufacturing cost can be reduced. Moreover, the thickness of the display device DSP can be reduced.

According to the comparative examples explained with reference to FIG. 23 to FIG. 25, as the sealing layer SEL is omitted, the manufacturing process can be further simplified, and thus, the manufacturing cost can be further reduced.

Moreover, the simplification of the manufacturing process allows the reduction in the number of manufacturing devices, the reduction in the size of manufacturing devices and the reduction in the installation area of manufacturing devices.

In the above embodiment, for example, each of the sealing layers SE1, SE2 and SE3 corresponds to the first sealing layer, and the sealing layer SEL corresponds to the second sealing layer. The resist RS1 corresponds to the first resist, and the resist RS2 corresponds to the second resist.

As explained above, the embodiment can provide a display device and a manufacturing method of a display device such that the manufacturing cost can be reduced.

All of the display devices and manufacturing methods thereof that can be implemented by a person of ordinary skill in the art through arbitrary design changes to the display device and manufacturing method thereof described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
a lower electrode provided in a display area which displays an image above the substrate;
an insulating layer which is formed of an inorganic insulating material and covers a peripheral portion of the lower electrode;
an organic layer which is provided on the lower electrode and includes a light emitting layer;
an upper electrode provided on the organic layer;
a cap layer provided on the upper electrode;
a partition which has a lower portion provided on the insulating layer, being in contact with the upper electrode and formed of a conductive material, and an upper portion provided on the lower portion, and surrounds the organic layer, the upper electrode and the cap layer;
a first sealing layer which is formed of an inorganic insulating material, is provided on the cap layer surrounded by the partition, is in contact with a side surface of the partition, extends to an upper side of the partition, and is spaced apart from the upper portion of the partition; and
a second sealing layer which is formed of an inorganic insulating material and directly covers the first sealing layer.

2. The display device of claim 1, further comprising a resin layer which covers the second sealing layer.

3. The display device of claim 2, further comprising a terminal electrically connected to a signal source outside the display area, wherein
an end portion of the second sealing layer and an end portion of the resin layer are located between the terminal and the display area.

4. The display device of claim 3, wherein
the end portion of the resin layer overlaps the end portion of the second sealing layer.

5. The display device of claim 3, wherein
the end portion of the resin layer is located between the terminal and the end portion of the second sealing layer.

6. The display device of claim 1, further comprising a void surrounded by the upper portion, the first sealing layer and the second sealing layer.

7. The display device of claim 1, wherein
the first sealing layer and the second sealing layer is formed of silicon nitride.

8. A display device comprising:
a substrate;
a lower electrode provided in a display area which displays an image above the substrate;
an insulating layer which is formed of an inorganic insulating material and covers a peripheral portion of the lower electrode;
an organic layer which is provided on the lower electrode and includes a light emitting layer;
an upper electrode provided on the organic layer;
a cap layer provided on the upper electrode;
a partition which has a lower portion provided on the insulating layer, being in contact with the upper electrode and formed of a conductive material, and an upper portion provided on the lower portion, and surrounds the organic layer, the upper electrode and the cap layer;
a first sealing layer which is formed of an inorganic insulating material, is provided on the cap layer surrounded by the partition, is in contact with a side surface of the partition, extends to an upper side of the partition, and is spaced apart from the upper portion of the partition; and
a resin layer which directly covers the first sealing layer, wherein
the resin layer is not covered with an inorganic insulating layer.

9. The display device of claim 8, wherein
a void surrounded by the upper portion and the first sealing layer is filled with the resin layer.

10. The display device of claim 2, further comprising a cover plate or a polarizer attached to the resin layer.

11. The display device of claim 1, wherein
the lower portion has a bottom layer provided on the insulating layer, and a stem layer provided between the bottom layer and the upper portion, and
the bottom layer and the upper portion protrude from a side surface of the stem layer.

12. A manufacturing method of a display device, the method comprising:
preparing a processing substrate by forming a lower electrode above a substrate, forming an insulating layer which covers a peripheral portion of the lower electrode, and forming a partition which has a lower portion located on the insulating layer and an upper portion located on the lower portion;
forming, on the lower electrode, a stacked film which includes an organic layer, an upper electrode and a cap layer, the organic layer including a light emitting layer;
forming a first sealing layer which is formed of an inorganic insulating material and covers the stacked film and the partition;
forming a second sealing layer which is formed of an inorganic insulating material and directly covers the first sealing layer; and
forming a resin layer on the second sealing layer.

13. The manufacturing method of claim 12, wherein
the forming the stacked film is an evaporation process using the partition as a mask in a vacuum environment having a first degree of vacuum, and
the forming the resin layer includes a process of applying a resinous material in an air atmosphere.

14. The manufacturing method of claim 13, wherein
after the process of applying the resinous material, the forming the resin layer further includes:
drying the resinous material in an environment where a pressure is less than the air atmosphere; and
curing the resinous material in the air atmosphere.

15. The manufacturing method of claim 12, wherein
before forming the second sealing layer, further,
a patterned first resist is formed on the first sealing layer in an air atmosphere, and
the first sealing layer and the stacked film are patterned using the first resist as a mask.

16. The manufacturing method of claim 15, wherein
further, a void is formed between the upper portion and the first sealing layer.

17. The manufacturing method of claim 16, wherein
after forming the second sealing layer, the void is surrounded by the upper portion, the first sealing layer and the second sealing layer.

18. The manufacturing method of claim 12, wherein
the second sealing layer is formed so as to cover a terminal electrically connected to a signal source,
the resin layer is formed so as not to overlap the terminal, and
after forming the resin layer, further, the second sealing layer is patterned using the resin layer as a mask.

19. The manufacturing method of claim 12, wherein
the second sealing layer is formed so as to cover a terminal electrically connected to a signal source, and
before forming the resin layer, further,
a second resist is formed on the second sealing layer in an air atmosphere,
the terminal is exposed by performing patterning of the second sealing layer using the second resist as a mask, and
the resin layer is formed so as not to overlap the terminal.

20. The manufacturing method of claim 13, wherein
a process of each of the first sealing layer and the second sealing layer is performed in a vacuum environment having a second degree of vacuum less than the first degree of vacuum.
